(19) United States
(12) Patent Application Publication
(10) Pub. No.: US 2014/0001586 A1
(43) Pub. Date: Jan. 2, 2014

(54) PERPENDICULARLY MAGNETIZED MAGNETIC TUNNEL JUNCTION DEVICE

(71) Applicant: INDUSTRIAL TECHNOLOGY RESEARCH INSTITUTE, Hsinchu (TW)

(72) Inventors: Kuei-Hung Shen, Hsinchu City (TW); Shan-Yi Yang, Hsinchu City (TW)

(73) Assignee: INDUSTRIAL TECHNOLOGY RESEARCH INSTITUTE, Hsinchu (TW)

(21) Appl. No.: 13/751,158

(22) Filed: Jan. 28, 2013

Related U.S. Application Data
(60) Provisional application No. 61/665,885, filed on Jun. 28, 2012.

(30) Foreign Application Priority Data
Oct. 19, 2012 (TW) 101138726

(51) Int. Cl. H01L 43/10

(52) U.S. Cl. CPC H01L 43/10
USPC 257/421

(57) ABSTRACT

Provided is a perpendicularly magnetized magnetic tunnel junction device including at least one multi-layer. The multi-layer includes a first metal oxide layer, a first ferromagnetic layer, a first modified layer and a second ferromagnetic layer. The first ferromagnetic layer is located on the first metal oxide layer, and the second ferromagnetic layer is located on the first ferromagnetic layer. The first modified layer is sandwiched between the first ferromagnetic layer and the second ferromagnetic layer.

### CROSS-REFERENCE TO RELATED APPLICATION

This application claims the priority benefits of U.S. provisional application Ser. No. 61/665,885, filed on Jun. 28, 2012 and Taiwan application serial no. 101138726, filed on Oct. 19, 2012. The entirety of each of the above-mentioned patent applications is hereby incorporated by reference herein and made a part of this specification.

### TECHNICAL FIELD

The disclosure relates to a perpendicular magnetized magnetic tunnel junction device including a multi-layer.

### BACKGROUND

Perpendicular magnetic anisotropy (PMA) spin-RAM have advantages such as an ability of minimization, a low power consumption, a high performance and a high reliability, and thus is very likely to become a mainstream technique of the next-generation new non-volatile memory. However, to enhance a magnetoresistance ratio of devices and to reduce write currents, a free layer still has to be mainly composed of films of perpendicularly magnetized CoFeB or CoFe. Nonetheless, since such free layer has a low equivalent magnetic anisotropy coefficient (K_{eff}) and a small thickness, a thermal stability thereof is low; thus, the free layer fails to be a non-volatile memory.

### SUMMARY

The disclosure provides a perpendicularly magnetized magnetic tunnel junction device including at least one multi-layer. The multi-layer includes a first metal oxide layer, a first ferromagnetic layer, a first modified layer and a second ferromagnetic layer. The first ferromagnetic layer is located on the first metal oxide layer. The second ferromagnetic layer is located on the first ferromagnetic layer. The first modified layer is sandwiched between the first ferromagnetic layer and the second ferromagnetic layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic cross-sectional view of a multi-layer according to an embodiment of the disclosure, wherein a first modified layer is a single continuous layer.

FIG. 1B is a schematic cross-sectional view of a multi-layer according to an embodiment of the disclosure, wherein a first modified layer is a multilayer continuous layer.

FIG. 1C is a schematic cross-sectional view of a multi-layer according to an embodiment of the disclosure, wherein a first modified layer is a non-continuous layer.

FIG. 1D is a schematic cross-sectional view of a multi-layer according to an embodiment of the disclosure, wherein a first modified layer is a plurality of granules.

FIG. 1E is a schematic cross-sectional view of a multi-layer according to an embodiment of the disclosure, wherein a first modified layer is clusters.

FIG. 2 is a schematic cross-sectional view of a perpendicularly magnetized magnetic tunnel junction device according to an embodiment of the disclosure.

FIG. 3 is a schematic cross-sectional view of another perpendicularly magnetized magnetic tunnel junction device according to an embodiment of the disclosure.

FIG. 4 is a schematic cross-sectional view of still another perpendicularly magnetized magnetic tunnel junction device according to an embodiment of the disclosure.

FIG. 5A illustrates magnetic hysteresis loops of stack structures of Examples 1-4 along a direction perpendicular to a surface.

FIG. 5B illustrates magnetic hysteresis loops of the stack structures of Examples 1-4 along a direction parallel to the surface.

FIG. 5C illustrates a correlation between a thickness of a tantalum layer and an equivalent magnetic anisotropy coefficient (K_{eff}) of the stack structures of Examples 1-4.

FIG. 6A illustrates out-of-plane magnetic hysteresis loops of stack structures of Comparative Examples 1-4.

FIG. 6B illustrates in-plane hysteresis loops of the stack structure of Comparative Example 1 along easy axis (annealing field direction, R0°) and hard axis (orthogonal to annealing field direction, R90°).

### DETAILED DESCRIPTION OF DISCLOSED EMBODIMENTS

The perpendicular magnetized magnetic tunnel junction device of the disclosure maintains a high magnetic resistance (MR) and a low write current and enhances a device thermal stability.

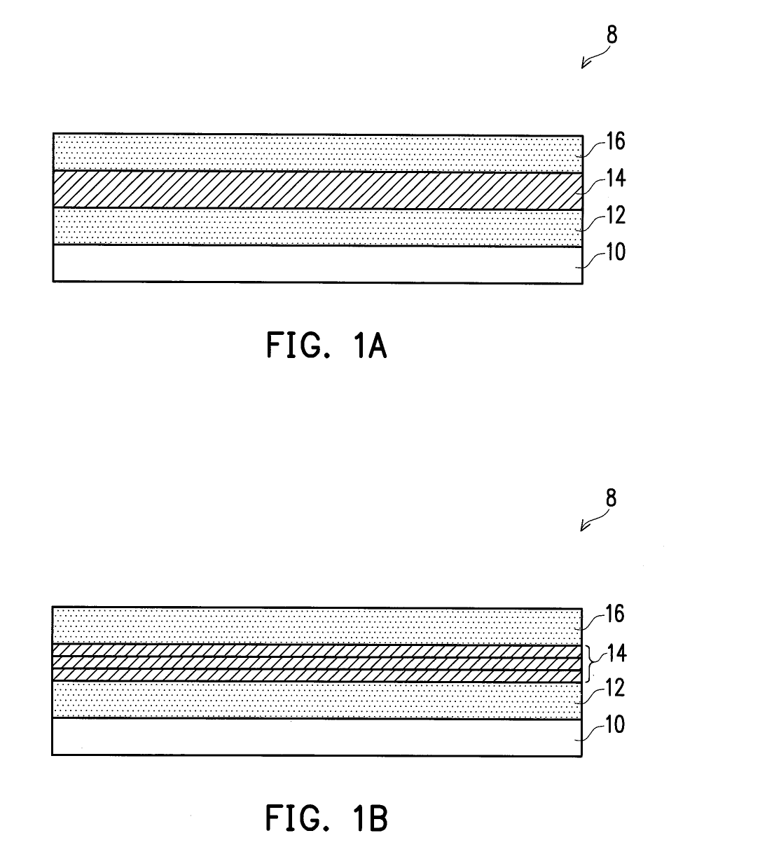

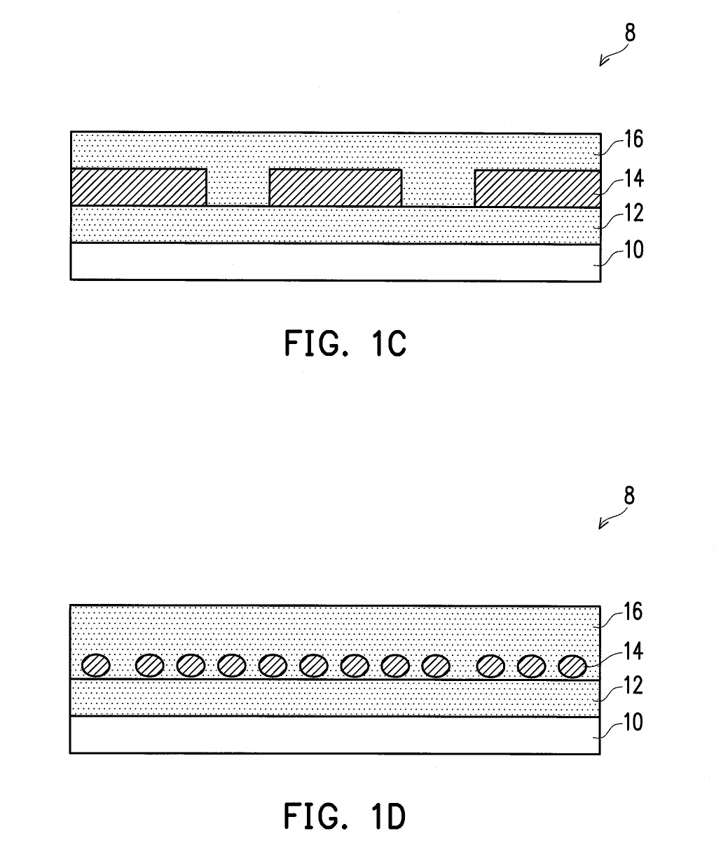

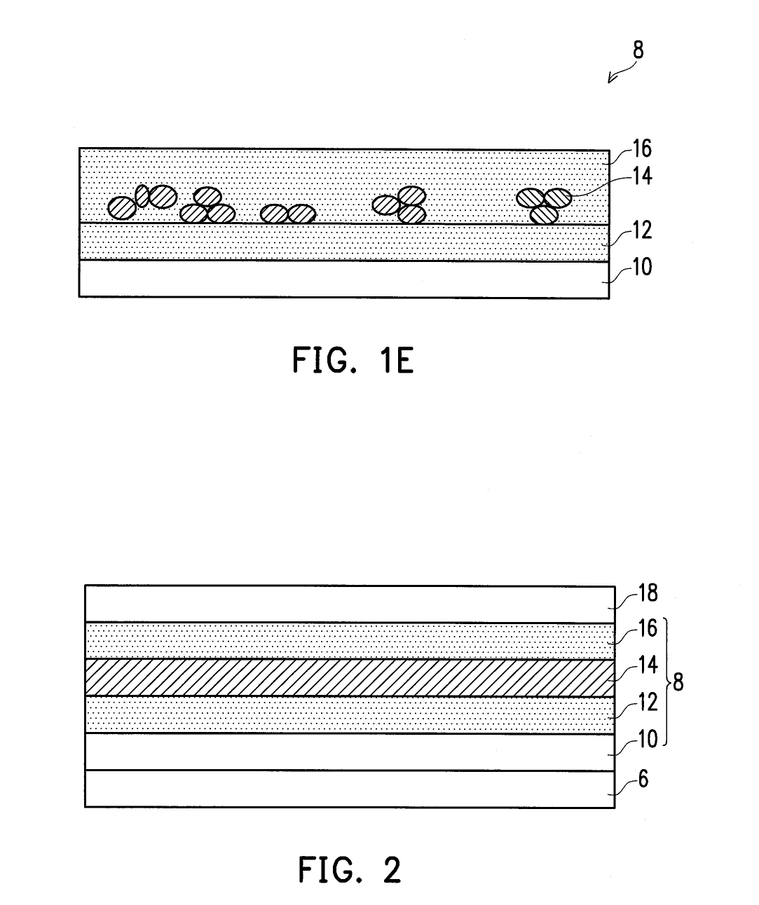

FIG. 1A is a schematic cross-sectional view of a multi-layer according to an embodiment of the disclosure, wherein a first modified layer is a single continuous layer.

Referring to FIG. 1A, a multi-layer 8 of the disclosure includes a first metal oxide layer 10, a first ferromagnetic layer 12, a first modified layer 14 and a second ferromagnetic layer 16.

A material of the first metal oxide layer 10 includes metal oxides, such as magnesium oxide, aluminum oxide, hafnium oxide, titanium oxide, zinc oxide or any combination thereof. A thickness of the first metal oxide layer 10 ranges from 7 angstroms to 9 angstroms, for example.

The first ferromagnetic layer 12 is located on the first metal oxide layer 10. The first ferromagnetic layer 12 is a perpendicular magnetic material and has a dopant, such as boron, but the dopant is not limited to boron. A material of the first ferromagnetic layer 12 is, for example, FeB, CoFeB or CoFeSiB or any combination thereof. A thickness of the first ferromagnetic layer 12 ranges from 7 angstroms to 13 angstroms, for example.

The second ferromagnetic layer 16 is located on the first ferromagnetic layer 12. The second ferromagnetic layer 16 is a perpendicular magnetic material and has a dopant, such as boron, but the dopant is not limited to boron. A material of the second ferromagnetic layer 16 is, for example, FeB, CoFeB or CoFeSiB or any combination thereof. The material of the second ferromagnetic layer 16 may be the same as or different from the material of the first ferromagnetic layer 12. A thickness of the second ferromagnetic layer 16 ranges from 7 angstroms to 13 angstroms, for example.

The first modified layer 14 is sandwiched between the first ferromagnetic layer 12 and the second ferromagnetic layer 16. The first modified layer 14 (especially during an annealing process) absorbs the dopant in the first ferromagnetic layer 12 and/or the dopant in the second ferromagnetic layer 16 to enhance crystallinity of the first ferromagnetic layer 12 and/or the second ferromagnetic layer 16 and increase a magnetoresistance ratio. In addition, the first modified layer 14 may increase a perpendicular magnetic anisotropy of an interface between the first ferromagnetic layer 12 and the first metal oxide layer 10 and/or an interface between the second ferromagnetic layer 16 and other metal oxide layers (such as a cap layer 18 or a tunnelling dielectric layer 20 in the following embodiments). Furthermore, the first modified layer 14 may also serve as a wetting layer to increase a continuity of a layer of the second ferromagnetic layer 16, so that the continuity of the layer of the second ferromagnetic layer 16 formed on the first modified layer 14 is better than a continuity of ferromagnetic layers formed on metal oxides directly.

In an embodiment, the materials of the first ferromagnetic layer 12 and the second ferromagnetic layer 16 include boron dopants, and the first modified layer 14 is of a material that absorbs boron. However, dopants that the first modified layer 14 of the disclosure absorbs are not limited to boron; anything that absorbs the dopants in the first ferromagnetic layer 12 and the second ferromagnetic layer 16 to enhance the crystallinity of the first ferromagnetic layer 12 and/or the second ferromagnetic layer 16 to increase the magnetoresistance ratio and the perpendicular magnetic anisotropy of an interface between the first ferromagnetic layer 12 and neighbouring metal oxides and/or an interface between the second ferromagnetic layer 16 and neighbouring metal oxides falls in the scope covered by the disclosure. A material of the first modified layer 14 includes metals or metal alloys, such as refractory metals, like Ta, Ti, Hf, Nb, V or Zr or any combination thereof, or alloys thereof. A thickness of the first modified layer 14 is less than or equal to 5 angstroms. In one embodiment, a thickness of the first modified layer 14 ranges from 1.5 angstroms to 5 angstroms, for example. If the first modified layer 14 is too thick, decoupling is caused. The first modified layer 14 may be a single continuous layer (FIG. 1A), a multilayer continuous layer (FIG. 1B), a plurality of granules (FIG. 1C), clusters (FIG. 1D), or a combination thereof; however, the disclosure is not limited thereto. The first modified layer 14 may be in any type that has properties of absorbing the dopants in the first ferromagnetic layer 12 and the second ferromagnetic layer 16.

The multi-layer 8 may be applied in a perpendicularly magnetized magnetic tunnel junction device and serve as a free layer. The multi-layer 8 applied in the perpendicularly magnetized magnetic tunnel junction device may serve as a free layer with a portion thereof or with the entirety thereof.

An embodiment of the multi-layer 8 applied in the perpendicularly magnetized magnetic tunnel junction device with a portion thereof serving as a free layer is illustrated with reference to FIG. 2 in the following.

FIG. 2 is a schematic cross-sectional view of a perpendicularly magnetized magnetic tunnel junction device according to an embodiment of the disclosure.

Referring to FIG. 2, in an embodiment, a perpendicularly magnetized magnetic tunnel junction device includes a pinned layer 6, the multi-layer 8 and a cap layer 18. The pinned layer 6 (or called a reference layer) is located under the first metal oxide layer 10 of the multi-layer 8. The pinned layer 6 may be any perpendicular magnetic material, such as a CoFeB single film, a Co/Pt multilayer film, a Co/Pd multilayer film, a Co/Ni multilayer film, a CoPd alloy film, a FePt alloy film, or a combination of a stack layer of the aforementioned materials.

The first metal oxide layer 10 serves as a tunnelling dielectric layer. The first ferromagnetic layer 12, the first modified layer 14 and the second ferromagnetic layer 16 serve as a free layer. The cap layer 18 is located on the multi-layer 8. A material of the cap layer 18 includes second metal oxides, such as magnesium oxide, aluminum oxide, hafnium oxide, titanium oxide, zinc oxide or any combination thereof. The (resistance area product, RA) of the first metal oxide layer 10 is greater than the RA of the second metal oxides of the cap layer 18, so that the first metal oxide layer 10 that serves as the tunnelling dielectric layer dominates the magnetoresistance ratio. An implementation way in which the RA of the first metal oxide layer 10 is greater than the RA of the second metal oxides of the cap layer 18 may be achieved by making a thickness of the first metal oxide layer 10 greater than a thickness of the cap layer 18.

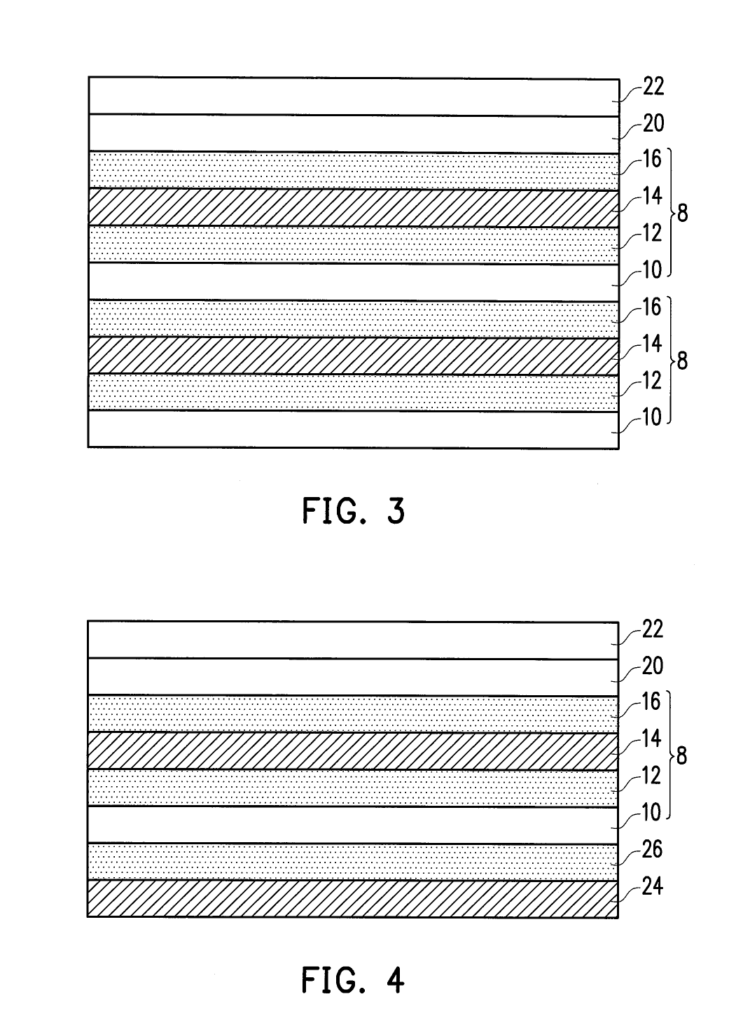

An embodiment of the multi-layer 8 applied in the perpendicularly magnetized magnetic tunnel junction device with the entirety thereof serving as a free layer is illustrated with reference to FIG. 3 in the following.

FIG. 3 is a schematic cross-sectional view of another perpendicularly magnetized magnetic tunnel junction device according to an embodiment of the disclosure.

When the entirety of the multi-layer 8 serves as the free layer, the free layer may include one multi-layer structure or two multi-layer structures (as shown in FIG. 3) or even more multi-layer structures, which may be represented as including (the multi-layer 8)ₙ, wherein n represents an integer greater than or equal to 1. One or more multi-layer structures may from a plurality of interfaces between the ferromagnetic layers and the metal oxides to increase the stability of the device.

Referring to FIG. 3, in an embodiment, the perpendicularly magnetized magnetic tunnel junction device includes more than one multi-layers 8 (the perpendicularly magnetized magnetic tunnel junction device in FIG. 3 includes two multi-layers 8), a tunnelling dielectric layer 20 and a pinned layer 22. The perpendicularly magnetized magnetic tunnel junction device may be represented as including (the multi-layer 8)ₙ/the tunnelling dielectric layer 20/the pinned layer 22, wherein n represents an integer greater than 1 (herein, n is 2 in correspondence to FIG. 3). The first metal oxide layer 10 of the multi-layers 8 is a seed layer. The first ferromagnetic layer 12, the first modified layer 14 and the second ferromagnetic layer 16 serve as a free layer. The tunnelling dielectric layer 20 is located on the multi-layers 8, and a material of the tunnelling dielectric layer 20 includes the second metal oxide layer, such as magnesium oxide, aluminum oxide, hafnium oxide, titanium oxide, zinc oxide or any combination thereof. The RA of the second metal oxide layer of the tunnelling dielectric layer 20 is greater than the RA of the first metal oxide layer, so that the tunnelling dielectric layer 20 dominates the magnetoresistance ratio. For example, an implementation way to make the RA of the second metal oxide layer of the tunnelling dielectric layer 20 greater than the RA of the first metal oxide layer may be implemented by making a thickness of the second metal oxide layer of the tunnelling dielectric layer 20 greater than a thickness of the first metal oxide layer 10 which serves as a seed layer. The pinned layer 20 is located on the tunnelling dielectric layer 20 and may be any perpendicular magnetic material, such as a CoFeB single film, a Co/Pt multilayer film, a Co/Pd multilayer film, a Co/Ni multilayer film, a CoPd alloy film, a FePt alloy film, or a combination of a stack layer of the aforementioned materials.

The multi-layer 8 may be applied in the perpendicularly magnetized magnetic tunnel junction device with the entirety thereof serving as a portion of a free layer, and such an embodiment is illustrated with reference to FIG. 4 in the following.

FIG. 4 is a schematic cross-sectional view of still another perpendicularly magnetized magnetic tunnel junction device according to an embodiment of the disclosure.

Referring to FIG. 4, in another embodiment, a free layer of a perpendicularly magnetized magnetic tunnel junction device further includes a second modified layer 24 and a third ferromagnetic layer 26 in addition to the multi-layer 8. In other words, a structure of the perpendicularly magnetized magnetic tunnel junction device may be represented as including the second modified layer 24/the third ferromagnetic layer 26/(the multi-layer 8)ₙ/the tunnelling dielectric layer 20/the pinned layer 22.

The second modified layer 24 is located under one or multi-layers 8 (one is illustrated in FIG. 4). The third ferromagnetic layer 26 is sandwiched between the first metal oxide layer 10 at the bottom of the multi-layers 8 and the second modified layer 24. The third ferromagnetic layer 26 has a dopant, such as boron, but the dopant is not limited to boron. A material of the third ferromagnetic layer 26 is, for example, FeB, CoFeB or CoFeSiB or any combination thereof. The material of the third ferromagnetic layer 26 may be respectively the same as or different from the materials of the first ferromagnetic layer 12 and the second ferromagnetic layer 16.

The second modified layer 24 absorbs the dopant in the third ferromagnetic layer 26 (for example, during an annealing process) to enhance crystallinity of the third ferromagnetic layer 26 to increase a magnetoresistance ratio and a perpendicular magnetic anisotropy of an interface between the third ferromagnetic layer 26 and the first metal oxide layer 10. In an embodiment, the material of the third ferromagnetic layer 26 includes boron dopants, and the second modified layer 24 is of a material that absorbs boron. However, dopants that the second modified layer 24 of the disclosure absorbs are not limited to boron; anything that absorbs the dopants in the third ferromagnetic layer 26 to enhance the crystallinity of the third ferromagnetic layer 26 to increase the magnetoresistance ratio and the perpendicular magnetic anisotropy of the interface between the third ferromagnetic layer 26 and the first metal oxide layer 10 falls in the scope covered by the disclosure. A material of the second modified layer 24 includes metals or metal alloys, such as refractory metals, like Ta, Ti, Hf, Nb, V or Zr or any combination thereof, or alloys thereof. A thickness of the second modified layer 24 ranges from 2 angstroms to 50 angstroms, for example. As described about the first modified layer 14, the second modified layer 24 may be a single continuous layer, a multilayer continuous layer, a non-continuous layer, a plurality of granules, clusters, or any combination thereof; however, the disclosure is not limited thereto.

In addition, the second modified layer 24 not only absorbs the dopants in the third ferromagnetic layer 26 but may also serve as a wetting layer to increase continuity of the film of the third ferromagnetic layer 26 above.

The structure of the perpendicularly magnetized magnetic tunnel junction device of the disclosure may from a plurality of interfaces between the ferromagnetic layers and the metal oxides to increase the perpendicular magnetic anisotropy.

In an embodiment, the perpendicularly magnetized magnetic tunnel junction device of the disclosure includes a MgO/CoFeB/M/CoFeB/MgO structure. A modified layer M is inserted between CoFeB in two MgO. The modified layer M are that during an annealing process, the modified layer M absorbs boron in CoFeB, so that crystallinity of CoFeB is enhanced to increase a magnetoresistance ratio and a perpendicular magnetic anisotropy of interfaces between CoFeB and MgO. In addition, the modified layer M may also serve as a wetting layer, so that the continuity of the CoFeB film on the modified layer M is better than the continuity of the CoFeB film on MgO.

In an exemplary embodiment, the perpendicularly magnetized magnetic tunnel junction device of the disclosure includes a free stack layer composed of a 6-angstrom-thick MgO layer/a 10-angstrom-thick CoFeB layer/a 3-angstrom-thick Ta layer/a 8-angstrom-thick CoFeB layer, and a tunneling layer composed of a 9-angstrom-thick MgO layer. A protection layer composed of a 30-angstrom-thick Ru layer and a 100-angstrom-thick Ta layer is formed on the free stack layer. An equivalent magnetic anisotropy coefficient (K_{eff}) of the perpendicularly magnetized magnetic tunnel junction device is about 1.4×10⁶ erg/cm³.

In another exemplary embodiment, the perpendicularly magnetized magnetic tunnel junction device of the disclosure includes a free stack layer composed of a 30-angstrom-thick Ta layer/a 8-angstrom-thick CoFeB layer/a 6-angstrom-thick MgO layer/a 10-angstrom-thick CoFeB layer/a 3-angstrom-thick Ta layer/a 8-angstrom-thick CoFeB layer, and a tunneling layer composed of a 9-angstrom-thick MgO layer. A protection layer composed of a 30-angstrom-thick Ru layer and a 100-angstrom-thick Ta layer is formed on the free stack layer. An equivalent magnetic anisotropy coefficient (K_{eff}) of the perpendicularly magnetized magnetic tunnel junction device is about 2.4×10⁶ erg/cm³.

### Examples 1-4

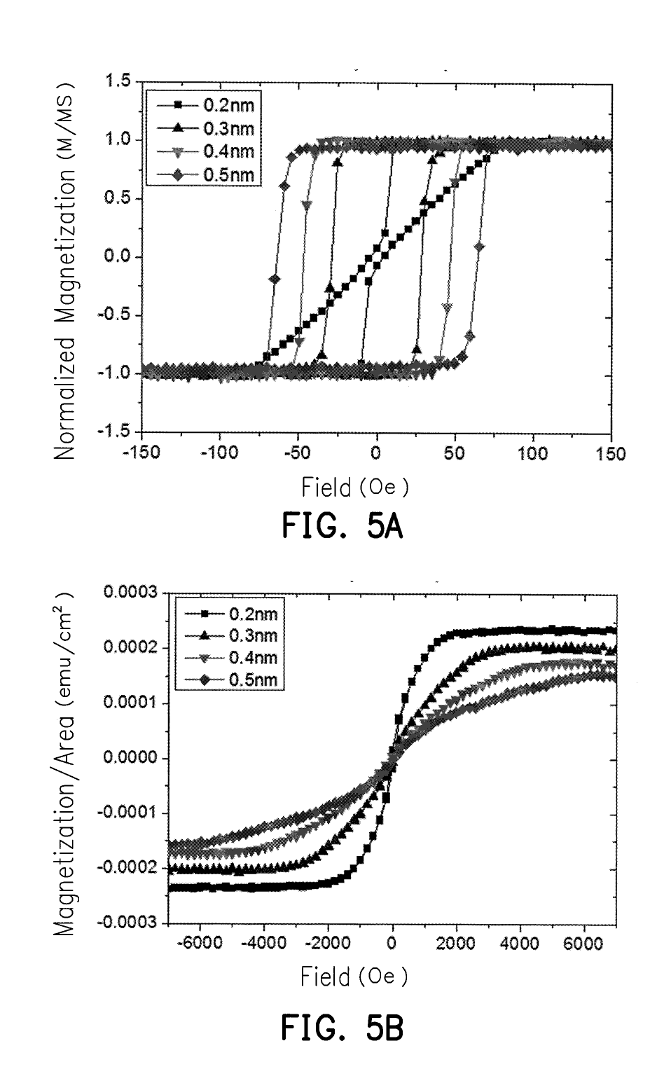

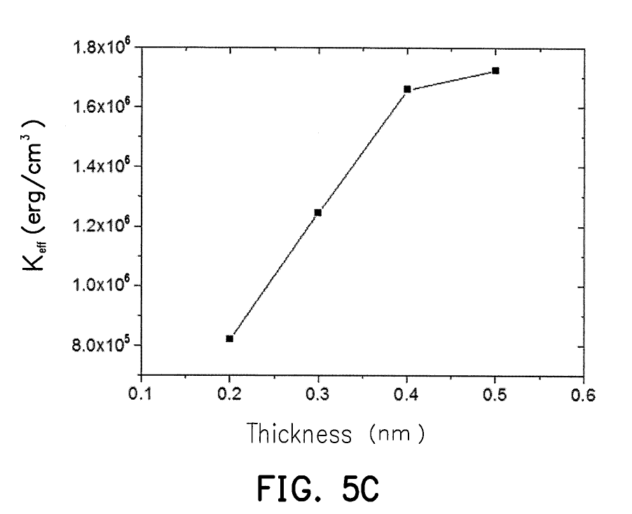

A 30-angstrom-thick Ta layer, a 9-angstrom-thick MgO layer, a 10-angstrom-thick CoFeB layer, a 2-angstrom-thick Ta layer, a 8-angstrom-thick CoFeB layer, a 9-angstrom-thick MgO layer, a 30-angstrom-thick Ru layer and a 600-angstrom-thick Ta layer are formed to manufacture a stack structure of Example 1. Examples 2-4 manufacture stack structures in a sequence similar to the sequence of Example 1, but Ta layers are manufactured to have different thicknesses (3 angstroms, 4 angstroms and 5 angstroms). Out-of-plane hysteresis loops of Examples 1-4 are as shown in FIG. 5A, and in-plane hysteresis loops of Examples 1-4 are as shown in FIG. 5B, and equivalent magnetic anisotropy coefficients of Ta layers with different thicknesses are as shown in FIG. 5G.

### Comparative Examples 1-4

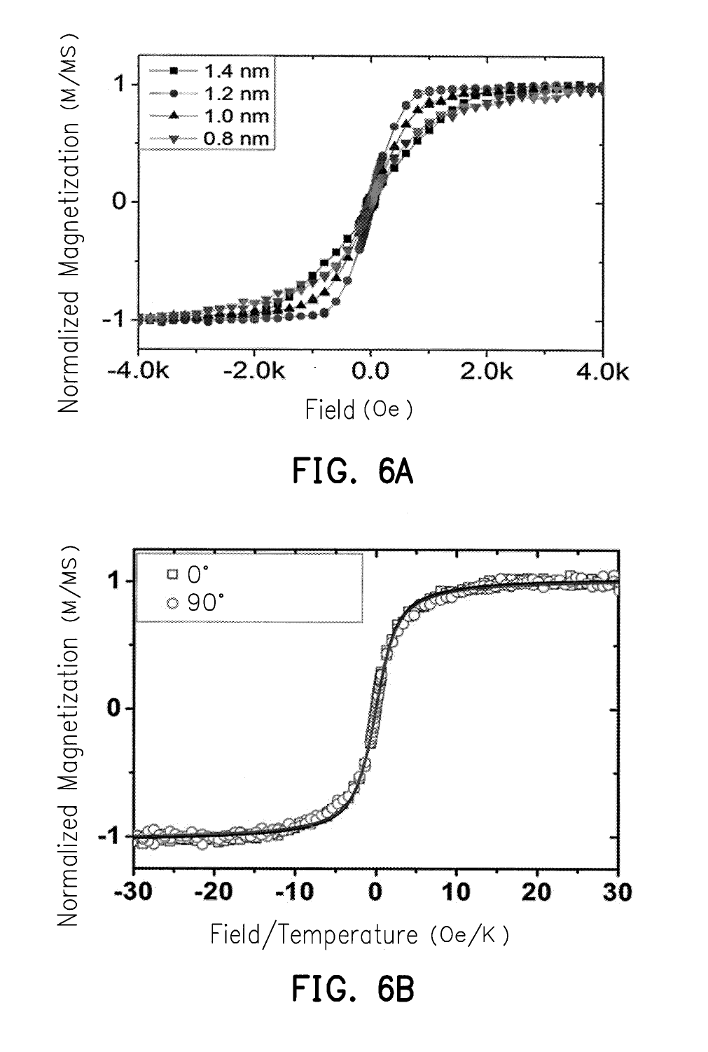

Comparative Examples 1-4 manufacture stack structures in a sequence similar to the sequence of Example 1, but the 10-angstrom-thick CoFeB layer, the 2-angstrom-thick Ta layer and the 8-angstrom-thick CoFeB layer are replaced by a CoFeB layer with different thicknesses (8 angstroms, 10 angstroms, 12 angstroms and 14 angstroms). Out-of-plane hysteresis loops of stack structures of Comparative Examples 1-4 as shown in FIG. 6A. In-plane hysteresis loops of the stack structure of Comparative Example 1 along easy axis (annealing field direction, R0°) and hard axis (orthogonal to annealing field direction, R90°) are as shown in FIG. 6B.

Results of FIGS. 5A, 5B and 5C show that the structures of Examples 1-4 exhibit the perpendicular magnetic anisotropy (PMA) property. Therefore, a thickness of CoFeB may be increased to 18 angstroms by inserting Ta into CoFeB.

Results of FIGS. 6A and 6B show that though Comparative Examples 1-4 have CoFeB/MgO interfaces, the stack structures having the CoFeB layers with different thicknesses are all unable to exhibit the PMA property. The CoFeB layer with a thickness over 10 angstroms exhibits in-plane magnetic anisotropy (IMA), and the CoFeB layer with a thickness of 8 angstroms exhibits a superparamagnetic property. Therefore, this may be relevant to the fact that boron does not easily diffuse from CoFeB, and thereby the perpendicular anisotropy of the CoFeB/MgO interface is influenced, or this may be relevant to the fact that CoFeB is likely to appear as discontinuous clusters on MgO.

Results of Examples 1-4 and Comparative Examples 1-4 show that compared with CoFeB with a conventional thickness (about 12 angstroms), by sandwiching a Ta layer (a dopant absorption layer) between two CoFeB layers, a retention is increased to about 1.5 times of the retention when there is a single CoFeB layer.

In addition, Ms of the stack structure with Ta inserted into CoFeB is higher than Ms of the stack structure without Ta inserted into CoFeB. Ms of the former may reach about 1570 emu/cm³, and Ms of the latter is 1240 emu/cm³. Therefore, the Ta layer is indeed able to absorb boron of CoFeB, increase the crystallinity of CoFeB, and thereby increases the perpendicular anisotropy of the CoFeB/MgO interface.

### Example 5

A 30-angstrom-thick Ta layer, a 11.5-angstrom-thick MgO layer, a 11 to 17-angstrom-thick CoFeB layer, a 3-angstrom-thick Ta layer, a 8 to 14-angstrom-thick CoFeB layer, a 11.5-angstrom-thick MgO layer and a cap layer (30-angstrom-thick Ru/100-angstrom-thick Ta) are sequentially formed to manufacture a stack structure, and interface anisotropy constant (Ki), volume anisotropyconstant (Kv) and demagnetization energy thereof are as shown in Table 1.

### Comparative Example 5

A 30-angstrom-thick Ta layer, a 8 to 20-angstrom-thick CoFeB layer, a 11.5-angstrom-thick MgO layer and a cap layer (30-angstrom-thick Ru/100-angstrom-thick Ta) are sequentially formed to manufacture a stack structure, and Ki, Kv and demagnetization energy thereof are as shown in Table 1.

### Comparative Example 6

A 30-angstrom-thick Ta layer, a 11.5-angstrom-thick MgO layer, a 10 to 22-angstrom-thick CoFeB layer, a 11.5-angstrom-thick MgO layer and a cap layer (30-angstrom-thick Ru/100-angstrom-thick Ta) are formed to manufacture a stack structure, and Ki, Kv and demagnetization energy thereof are as shown in Table 1.

TABLE 1

| | Interface | Volume | Demagnet- |
|---|---|---|---|
| | Anisotropy | Anisotropy | ization |
| | Constant | Constant | Energy |
| | (Ki, erg/cm²) | (Kv, mJ/m³) | (mJ/m³) |
| Example 5 | 1.90 | −1.16 | −1.55 |
| Comparative | 1.32 | −1.91 | −1.60 |
| Example 5 | | | |
| Comparative | 1.03 | −0.77 | −0.99 |
| Example 6 | | | |

The definition of the equivalent anisotropy coefficient is as follows:

K_{eff}=Kv−2πMs²+Ki/t

In this equation; K_{eff} is an equivalent magnetic anisotropy coefficient; Kv is a volume anisotropy coefficient; Ki is an interface anisotropy coefficient; Ms is saturation magnetization; and t is an equivalent thickness of magnetic layers.

Results of Table 1 show that compared with Comparative Example 5, Example 5 has a greater Ki and a smaller Kv, which increases a thickness of the free layer of PMA and improves the retention and thermal stability of the device. Compared with Comparative Example 6, the demagnetization energy of Example 5 changes from −0.99 mJ/m³ to −1.55 mJ/m³, which shows that Example 5 has a higher crystallinity.

In summary of the above, the multi-layer structure of the disclosure includes the ferromagnetic layers with modified layers inserted therein, and the modified layers absorb the dopants in the ferromagnetic layers during the annealing process to enhance the crystallinity of the ferromagnetic layers, increase the perpendicular magnetic anisotropy of the interfaces between the ferromagnetic layers and the metal oxide layers, and increase the total thickness of the ferromagnetic layers (the free layers) to increase the magnetic reversal energy barrier (Eb), so that the thermal stability and the retention of the device are enhanced.

Although the disclosure has been described with reference to the above embodiments, they are not intended to limit the disclosure. It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A perpendicularly magnetized magnetic tunnel junction device, comprising:
at least one multi-layer, the multi-layer comprising:
a first metal oxide layer;
a first ferromagnetic layer located on the first metal oxide layer;
a second ferromagnetic layer located on the first ferromagnetic layer; and
a first modified layer sandwiched between the first ferromagnetic layer and the second ferromagnetic layer.

2. The perpendicularly magnetized magnetic tunnel junction device according to claim 1, wherein the first ferromagnetic layer and the second ferromagnetic layer respectively have dopants, and the first modified layer absorbs a portion of the dopants.

3. The perpendicularly magnetized magnetic tunnel junction device according to claim 2, wherein the dopants comprise boron.

4. The perpendicularly magnetized magnetic tunnel junction device according to claim 1, wherein a material of the first modified layer comprises Ta, Ti, Hf, Nb, V or Zr or an alloy thereof.

5. The perpendicularly magnetized magnetic tunnel junction device according to claim 1, wherein the first modified layer is a single continuous layer, a multilayer continuous layer, a non-continuous layer, a plurality of granules, a plurality of clusters, or any combination thereof.

6. The perpendicularly magnetized magnetic tunnel junction device according to claim 1, wherein materials of the first ferromagnetic layer and the second ferromagnetic layer respectively comprise FeB, CoFeB, CoFeSiB or any combination thereof.

7. The perpendicularly magnetized magnetic tunnel junction device according to claim 1, wherein a material of the first metal oxide layer comprises magnesium oxide, aluminum oxide, hafnium oxide, titanium oxide, zinc oxide or any combination thereof.

8. The perpendicularly magnetized magnetic tunnel junction device according to claim 1, wherein the multi-layer is a free layer.

9. The perpendicularly magnetized magnetic tunnel junction device according to claim 1, wherein two or more multi-layers serves as a free layer.

10. The perpendicularly magnetized magnetic tunnel junction device according to claim 9, further comprising:
a second modified layer located under the two or more multi-layer; and
a third ferromagnetic layer sandwiched between the first metal oxide layer and the second modified layer.

11. The perpendicularly magnetized magnetic tunnel junction device according to claim 8, further comprising:
a second modified layer located under the first metal oxide layer; and
a third ferromagnetic layer sandwiched between the first metal oxide layer and the second modified layer.

12. The perpendicularly magnetized magnetic tunnel junction device according to claim 8, further comprising a tunnelling dielectric layer and a pinned layer, wherein the tunnelling dielectric layer comprises a second metal oxide layer located on the multi-layer, the pinned layer is located on the tunnelling dielectric layer, and a resistance area product of the second metal oxide layer is greater than a resistance area product of the first metal oxide layer.

13. The perpendicularly magnetized magnetic tunnel junction device according to claim 1, wherein the first metal oxide layer is a tunnelling dielectric layer, and the first ferromagnetic layer, the first modified layer and the second ferromagnetic layer are a free layer and further comprise a pinned layer and a cap layer, wherein the pinned layer is located under and contacts the first metal oxide layer, the cap layer is located on the second ferromagnetic layer, a material of the cap layer comprises a second metal oxide layer, and a resistance area product of the first metal oxide layer is greater than a resistance area product of the second metal oxide layer.
